(19) United States
(12) Patent Application Publication
(10) Pub. No.: US 2010/0233881 A1
(43) Pub. Date: Sep. 16, 2010

(54) METHOD OF MANUFACTURING SUPPORTING STRUCTURES FOR STACK CAPACITOR IN SEMICONDUCTOR DEVICE

(75) Inventors: Chung-Chiang Min, Banqiao City (TW); Chang-Yao Hsieh, Beidou Town (TW)

Correspondence Address: VOLPE AND KOENIG, P.C., UNITED PLAZA, 30 SOUTH 17TH STREET, PHILADELPHIA, PA, 19103, US

(73) Assignee: NANYA TECHNOLOGY CORP., Tao-Yuan Hsien (TW)

(21) Appl. No.: 12/492,462

(22) Filed: Jun. 26, 2009

(30) Foreign Application Priority Data
Mar. 16, 2009 (TW) 098108511

(51) Int. Cl. H01L 21/302

(52) U.S. Cl. 438/700; 257/E21.214

(57) ABSTRACT

A method of manufacturing a supporting structure for a stack capacitor in a semiconductor device is provided. The method includes the following steps. The first step is providing a multi-layer structure including an etching stop layer, a silicon oxide layer and a silicon nitride layer. The second step is etching the silicon nitride layer and the silicon oxide layer to form a plurality of filling recesses in the silicon oxide layer, in which each the filling recess has a lateral surface and a bottom surface. The third step is forming a protecting layer at each the lateral surface. The fourth step is etching the silicon oxide layer to expose the etching stop layer. The fifth step is removing the protecting layer on the each lateral surface, thereby forming the supporting structure.

### FIELD OF THE INVENTION

The present invention relates to a method of manufacturing a stack capacitor in a semiconductor device, and more particularly to a method of manufacturing a supporting structure for a stack capacitor in a semiconductor device.

### BACKGROUND OF THE INVENTION

Please refer to FIGS. 1(a)-1(c), which are schematic diagrams showing the method of manufacturing a supporting structure for a stack capacitor in a semiconductor according to the prior art. In FIG. 1(a), an etching stop layer 1 is located at the bottom of the structure, and a silicon oxide layer 2, a silicon nitride layer 3, a carbonized layer 4 and a photo resistor layer 5 are sequentially formed on the etching stop layer 1. At least one or more etching windows 50 are formed in the photo resistor layer 5. The etching windows 50 are formed on the carbonized layer 4, for performing an etching to the carbonized layer 4. After the etching, plural etching windows 40 in the carbonized layer 4 are shown in FIG. 1(b). Then, another etching is performed for the silicon nitride layer 3 and the silicon oxide layer 2, to form deep recesses having a high depth-to-width ratio, namely filling recesses 20. The result is shown in FIG. 1(c). The filling recesses 20 are used to fill materials for making stack capacitors (not shown). On the other hand, the silicon oxide layer 2 between the filling recesses 20 becomes a supporting structure 22 for the stack capacitors.

A drawback of the traditional manufacturing method is that lateral etching occurs on the lateral surfaces of the supporting structure 22 and ends up with lateral etching concaves 21 as shown in FIG. 1(c), which causes the portion of the supporting structure 22 near the lateral etching concaves 21 to be thinner and relatively fragile.

Please refer to FIGS. 2(a)-2(c), which are schematic diagrams showing the method of manufacturing a stack capacitor in a semiconductor device by using a conventional supporting structure. FIG. 2(a) shows an etching stop layer 1 at the lowest position of the structure. A silicon oxide layer 2 is formed on the etching stop layer 1, and a crossbeam layer 3 is formed on the silicon oxide layer 2. The aspect ratio dependent effect (ARDE) due to high aspect ratio etching is also shown in FIGS. 2(a)-2(c). The ARDE causes slope 2′ at the lower portion of the lateral surface of the filling recesses 20. That is, the width of the filling recesses 20 decreases as the depth thereof increases. As for the supporting structure 22, the width thereof increases as the depth thereof increases, and a neck 2″ is formed thereon. Referring to FIG. 2(a) again, a lower electrode 6a of a stack capacitor 6 (refer to FIG. 2(c)) is formed on the supporting structure 22. The silicon nitride layer 3 acts as a crossbeam to sustain the structural stability of the lower electrode 6a.

FIG. 2(b) shows the removal of the supporting structure 22. FIG. 2(c) shows the formation of an isolation layer 6b and an upper electrode 6c of the stack capacitor 6. It can be observed that, due to the existence of the lateral etching concaves, a space (the neck 2″) between the two lower electrodes 6a is limited which results in a smaller space between two adjacent isolation layers 6b. Consequently, a blocking area 6′ of the upper electrode 6c is likely to be formed, for the space originally being the neck 2″ becomes too small to allow the material for the upper electrode 6c to pass through. Since the material for the upper electrode 6c cannot fully cover the top of the isolation layer 6b, the capacitor function at the blocking area 6′ of the stack capacitor will be different from that at the region without blocking areas. This ends up with the symptom of unstable charging/discharging for the capacitor, which may further cause defects of the capacitors.

Therefore, a new supporting structure for the production of stack capacitors in semiconductor devices to avoid the drawback due to ARDE in the prior art is required, which is indeed what the present invention intends to resolve.

### SUMMARY OF THE INVENTION

In accordance with one aspect of the present invention, a method of manufacturing a supporting structure for a stack capacitor in a semiconductor device is provided. The method includes the following steps. The first step is providing a multi-layer structure including a silicon oxide layer and a silicon nitride layer. The second step is etching the silicon nitride layer and the silicon oxide layer to form a plurality of filling recesses in the silicon oxide layer, in which each of the filling recesses has a lateral surface and a bottom surface. The third step is forming a protecting layer at the lateral surface of each of the filling recesses. The fourth step is etching the silicon oxide layer. The fifth step is removing the protecting layer on the lateral surface of each of the filling recesses, thereby forming the supporting structure. Preferably, the multi-layer structure further includes a polysilicon layer, a carbonized layer and an etching stop layer, and a process of providing the multiple layer structure includes steps of (a) providing the etching stop layer; (b) forming the silicon oxide layer on the etching stop layer; (c) forming the silicon nitride layer on the silicon oxide layer; (d) forming the polysilicon layer on the silicon nitride layer; (e) forming the carbonized layer on the polysilicon layer; (f) forming a plurality of carbonized etching windows in the carbonized layer to partially expose the polysilicon layer; and (g) forming a plurality of polysilicon etching windows in the exposed polysilicon layer to partially expose the silicon nitride layer and form a remnant polysilicon layer.

Preferably, the silicon oxide layer comprises one selected from a group consisting of a boron glass, a phosphorus glass and a non-doping silica glass.

Preferably, the protecting layer has a high etching selectivity for the silicon oxide layer such that the lateral surface of each of the filling recesses is prevented from being etched, and the protecting layer comprises one selected from a group consisting of a polysilicon, a silicon nitride and an aluminum oxide.

Preferably, the second step is performed by using the remnant polysilicon layer as a mask.

Preferably, the third step further includes the following sub-steps: forming a protecting layer on the bottom surface simultaneously as forming the protection layer at the each lateral surface; and removing the protection layer on the each bottom surface to expose the silicon oxide layer thereunder.

Preferably, the fifth step includes a sub-step of removing the remnant polysilicon layer.

In accordance with another aspect of the present invention, a method of manufacturing a supporting structure for a stack capacitor in a semiconductor device is provided. The method includes the following steps. The first step is providing a supporting structure layer. The second step is forming a plurality of filling recesses in the supporting structure layer, in which each the filling recess has a lateral surface and a bottom surface. The third step is forming a protecting layer on each the lateral surface. The fourth step is etching the supporting structure layer. The fifth step is removing the protecting layer on the each lateral surface, thereby forming the supporting structure.

The above objects and advantages of the present invention will become more readily apparent to those ordinarily skilled in the art after reading the details set forth in the descriptions and drawings that follow, in which:

### BRIEF DESCRIPTION OF THE DRAWINGS

FIGS. 1(a)-1(c) are schematic diagrams showing the method of manufacturing a supporting structure for a stack capacitor in a semiconductor according to the prior art;

FIGS. 2(a)-2(c) are schematic diagrams showing the method of manufacturing a stack capacitor in a semiconductor device by using a conventional supporting structure; and

FIGS. 3(a)-3(f) are schematic diagrams showing the method of manufacturing a supporting structure for a stack capacitor in a semiconductor device according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

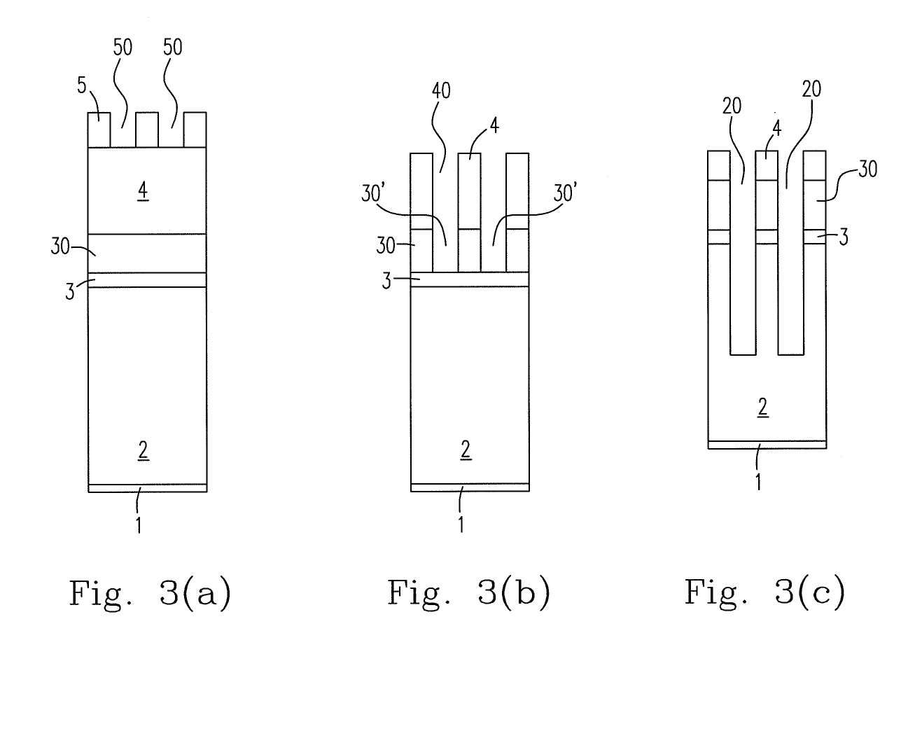

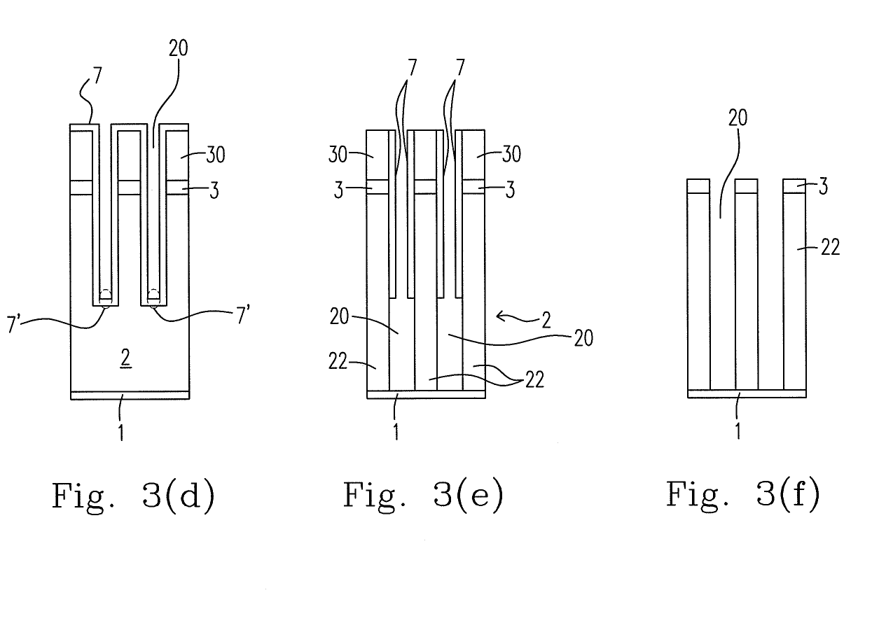

Please refer to FIGS. 3(a)-3(f), which are schematic diagrams showing the method of manufacturing a supporting structure for a stack capacitor in a semiconductor device according to a preferred embodiment of the present invention. The manufacturing method briefly includes the following steps. As shown in FIG. 3(a), firstly an etching stop layer 1 is provided; a silicon oxide layer 2 is formed on the etching stop layer; a silicon nitride layer 3 is formed on the silicon oxide layer 2; a polysilicon layer 30 is formed on the silicon nitride layer 3; a carbonized layer 4 is formed on the polysilicon layer 30; and a photo resistor 5 is formed on the carbonized layer 4, in which plural photo resistor etching windows 50 are formed on the carbonized layer 4 to expose the portions of the carbonized layer 4 to be etched out. Next, please refer to FIG. 3(b). Following the steps set forth above, then the portions of the carbonized layer 4 under the photo resistor etching windows 50 are etched out and a plurality of carbonized etching windows 40 are formed on the polysilicon layer 30, to expose the portions of the polysilicon layer 30 to be etched out. The portions of the polysilicon layer 30 under the carbonized etching windows 40 are etched out and a plurality of polysilicon etching windows 30′ are formed (below the carbonized etching windows 40 and above the silicon nitride layer 3), to expose the portions of the silicon nitride layer 3 to be etched out.

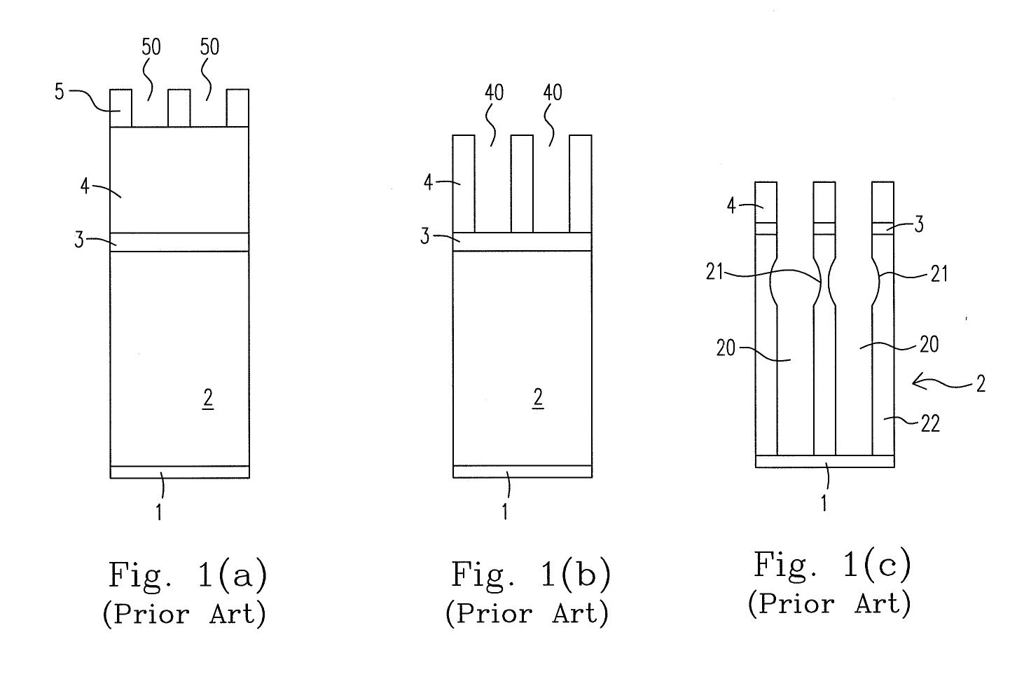

Please refer to FIGS. 3(c) and 3(d), taking advantage of the polysilicon etching windows 30′, the silicon nitride layer 3 is etched through, and a first etching to the silicon oxide layer 2 is performed to form a plurality of filling recesses 20 thereon. It is to be noted that the filling recesses 20 have not been completed at this moment, since the depth thereof has not reached the etching stop layer 1. The first etching should be stopped at the depth when the lateral etching concave 21 in FIG. 1(c) has not been formed yet. In FIG. 3(d), a protecting layer 7 is formed on the lateral surface of the filling recesses 20, to avoid etching occurring at the portion of the silicon oxide 2 covered by the protecting layer 7. During the process of forming the protecting layer 7 on the lateral surface of the filling recesses 20, the protecting layer 7 might cover the bottom surface of the filling recesses 20 simultaneously. Therefore, a protecting layer 7′ on the bottom surface of the filling recesses 20 is to be removed, to expose the portion of the silicon oxide layer 2 under the filling recesses 20.

Please refer to FIG. 3(e), wherein a second etching is performed for the silicon oxide layer 2 not covered by the protecting layer 7 until the etching stop layer 1 is exposed. Then the protecting layer 7 is removed. Preferably, the protecting layer 7 is removed by means of wet etching, and the silicon oxide layer 2 has high etching selectivity during the wet etching process. The polysilicon layer 30 is also removed if necessary. Now plural supporting props 22 are formed. According to FIG. 3(f), the bottom of the filling recesses 20 is at the etching stop layer 1, and the silicon nitride layer 3 acts as crossbeams to support and divide the supporting props 22. The process for manufacturing the supporting structure for a stack capacitor in a semiconductor device is now completed.

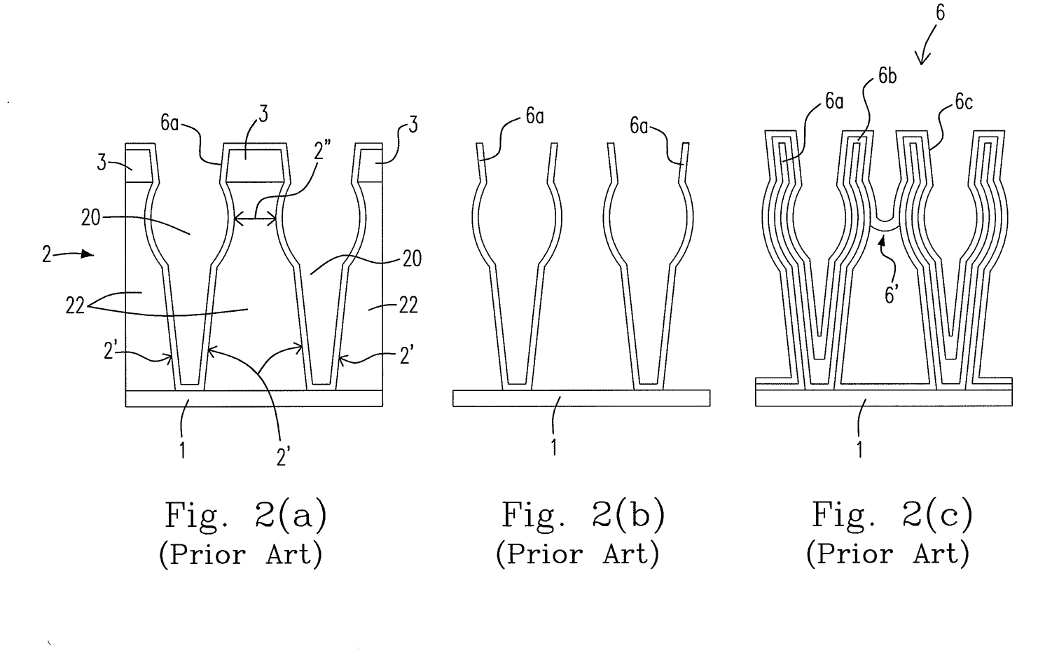

It is observed from FIG. 3(e) that, through the use of the protecting layer 7, the present invention avoids the lateral etching concave 21 (refer to FIG. 1(c)) caused by operations with high aspect ratio and significantly reduces the slop 2′ (refer to FIG. 2(a)) due to ARDE effect. Owing to the protecting layer 7, the etching process is concentrated on the areas not covered by the protecting layer 7, and the occurrence of the slop 2′ is therefore retarded.

Please refer to FIG. 3(f) again, wherein the silicon nitride layer 3 is to provide supporting for the stack capacitor 6 (refer to FIGS. 2(a)-(c)) when the electrodes are formed, so the silicon nitride layer 3 is formed on the silicon oxide layer 2. The silicon nitride layer 3 acts as a spacing crossbeam, which is a beam structure also providing the function of a spacer, to sustain the structural stability of the lower electrode 6a and avoid any falling or contact of the lower electrodes 6a at both sides of the crossbeam.

Please refer to FIGS. 3(a)-3(f) again. From a structural aspect, the method of manufacturing the supporting structure for a stack capacitor in a semiconductor device provided by the present invention includes providing a supporting structure layer 2 to support the material for producing the stack capacitor 6 (refer to FIG. 2(a)), that is, to allow the material for producing the stack capacitor 6 to form a shape on the support structure 22. Therefore, the supporting structure 22 can also be considered as a kind of mold. The supporting structure layer 2 is made of a material selected from a group consisting of a boron glass, a phosphorus glass and a non-doping silica glass.

Please refer to FIG. 3(c), wherein a first etching to the supporting structure layer 2 is performed and a filling recess 20 is formed. Referring to FIG. 3(d), a protecting layer 7 is formed on the lateral surface of the filling recess 20. The protecting layer 7 has a higher etching selectivity versus the supporting structure layer 2, so the lateral surface of the filling recess is prevented from being etched. Preferably, the protecting layer and is made of a material selected from a group consisting of a polysilicon, a silicon nitride and an aluminum oxide.

Referring to FIG. 3(e), a second etching to the supporting structure 2 is performed. Finally, the protecting layer 7 is removed and the residue polysilicon layer 30 on the silicon nitride layer 3 is removed, to end up with a plurality of supporting props 22, crossbeams 3 thereon, and the filling recesses 20 thereinbetween. Thus, the supporting structure for the stack capacitors in a semiconductor device is completed. Besides, usually a protecting layer 7′ on the bottom surface of the filling recess 20 is simultaneously formed, when the protection layer 7 at each lateral surface of the filling recess 20 is formed. Accordingly, the protecting layer 7′ on the bottom surface of the filling recess 20 is to be removed after forming the protecting layer 7, to expose the supporting structure layer 2 at the bottom of the filling recess 20 for the mentioned second etching.

According to FIGS. 3(a)-3(f), practically, the summed etching depth of the first etching and the second etching nearly equals to the depth of the filling recess 20. In general, the etching depth in each period of etching is mainly related to the ARDE due to the high aspect ratio and the timing for the occurrence of the lateral etching concaves 21 (refer to FIG. 1(c)) as well. The lateral etching concave 21 and the slope 2′ might begin to form, or the forming process for either one might begin to be expedited, when the etching to the supporting structure layer 2 reaches a certain depth. Thus, the etching process for the supporting structure layer 2 shall be stopped at a proper timing before the mentioned defects occur, and a protecting layer 7 shall be formed on the lateral surface of the newly formed recess. The skilled person in this art can obtain the abovementioned timing via simple experiments. Therefore, the total number of etching periods may not be 2. It can be 3 or more, as long as the protecting layer 7 is needed to be formed to timely prevent the occurrence of the mentioned two defects, i.e. the lateral etching concave 21 and the slope 2′.

Besides, a crossbeam layer 3 is formed on the supporting structure layer 2 to provide supporting for the electrodes (refer to the lower electrode 6a in FIG. 2(a)) of the stack capacitor 6 when the electrodes are produced. Usually the crossbeam layer 3 is made of silicon nitride.

Based on the embodiments set forth above, the present invention provides the method of forming protecting layers on the surface of the deep recesses made via deep etching processes, which can effectively retard, or even avoid, the formation of lateral etching concaves and significantly reduce the ARDE effect as well. As a result, the stack capacitors of the semiconductor devices manufactured with the supporting structure provided by the present invention do not have the issue of blocking as shown in FIGS. 2(a)-2(c). Hence, the performance of the stack capacitors is more stable and the yield rate is significantly enhanced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims that are to be accorded with the broadest interpretation so as to encompass all such modifications and similar structures.

What is claimed is:

1. A method of manufacturing a supporting structure for a stack capacitor in a semiconductor device, comprising steps of:
(a) providing a multi-layer structure including a silicon oxide layer and a silicon nitride layer;
(b) etching the silicon nitride layer and the silicon oxide layer to form a plurality of filling recesses in the silicon oxide layer, wherein each of the filling recesses has a lateral surface and a bottom surface;
(c) forming a protecting layer at the lateral surface of each of the filling recesses;
(d) etching the silicon oxide layer; and
(e) removing the protecting layer on the lateral surface of each of the filling recesses, and thereby forming the supporting structure.

2. A manufacturing method as claimed in claim 1, wherein the silicon oxide layer comprises a material selected from a group consisting of a boron glass, a phosphorus glass and a non-doping silica glass.

3. A manufacturing method as claimed in claim 1, wherein the protecting layer has a high etching selectivity for the silicon oxide layer such that the lateral surface of each of the filling recesses is prevented from being etched.

4. A manufacturing method as claimed in claim 1, wherein the multi-layer structure further includes a polysilicon layer, a carbonized layer and an etching stop layer, and a process of providing the multiple layer structure comprises steps of:
providing the etching stop layer;
forming the silicon oxide layer on the etching stop layer;
forming the silicon nitride layer on the silicon oxide layer;
forming the polysilicon layer on the silicon nitride layer; and
forming the carbonized layer on the polysilicon layer.

5. A manufacturing method as claimed in claim 4, wherein the step (a) further comprises sub-steps of:
forming a plurality of carbonized etching windows in the carbonized layer to partially expose the polysilicon layer; and
forming a plurality of polysilicon etching windows in the exposed polysilicon layer to partially expose the silicon nitride layer and form a remnant polysilicon layer.

6. A manufacturing method as claimed in claim 5, wherein the step (b) is performed by using the remnant polysilicon layer as a mask.

7. A manufacturing method as claimed in claim 1, wherein the step (c) further comprises a sub-step of:
forming a protecting layer on the bottom surface simultaneously as forming the protection layer at the each lateral surface.

8. A manufacturing method as claimed in claim 7, wherein the step (c) further comprises a sub-step of:
removing the protection layer on the bottom surface to expose the silicon oxide layer thereunder.

9. A manufacturing method as claimed in claim 1, wherein the protecting layer comprises a material selected from a group consisting of a polysilicon, a silicon nitride and an aluminum oxide.

10. A manufacturing method as claimed in claim 1, wherein the step (e) further comprises a sub-step of:
removing the remnant polysilicon layer.

11. A manufacturing method as claimed in claim 1, wherein the protecting layer comprises a material selected from a group consisting of a polysilicon, a silicon nitride and an aluminum oxide.

12. A method of manufacturing a supporting structure for a stack capacitor in a semiconductor device, comprising steps of:
(a) providing a supporting structure layer;
(b) forming a plurality of filling recesses in the supporting structure layer, wherein each the filling recess has a lateral surface and a bottom surface;
(c) forming a protecting layer on each the lateral surface;
(d) etching the supporting structure layer; and
(e) removing the protecting layer on the each lateral surface, and thereby forming the supporting structure.

13. A manufacturing method as claimed in claim 12, wherein the supporting structure layer comprises a material selected from a group consisting of a silicon oxide, a boron glass, a phosphorus glass and a non-doping silica glass.

14. A manufacturing method as claimed in claim 12, wherein the protecting layer comprises a material selected from a group consisting of a polysilicon, a silicon nitride and an aluminum oxide.

15. A manufacturing method as claimed in claim 12, wherein the step (c) further comprises a sub-step of:
forming a protecting layer on the bottom surface simultaneously as forming the protection layer at the each lateral surface.

16. A manufacturing method as claimed in claim 15, wherein the step (c) further comprises a sub-step of:
removing the protection layer on the each bottom surface to expose the silicon oxide layer thereunder.
